(19) United States
(12) Patent Application Publication
(10) Pub. No.: US 2023/0110307 A1
(43) Pub. Date: Apr. 13, 2023

(54) SHAPED ELECTRICAL INTERCONNECTIONS FOR MULTI-LAYER HEATER CONSTRUCTIONS

(71) Applicant: WATLOW ELECTRIC MANUFACTURING COMPANY, St. Louis, MO (US)

(72) Inventors: Julian MICHELSEN, Scheffau am Tennengebirge (AT); Martin WALLINGER, Abtenau (AT); Gernot TEUFL, Hallein (AT)

(73) Assignee: WATLOW ELECTRIC MANUFACTURING COMPANY, St. Louis, MO (US)

(21) Appl. No.: 17/497,280

(22) Filed: Oct. 8, 2021

(51) Int. Cl. H05B 3/28; H01L 21/67

(52) U.S. Cl. CPC H05B 3/28; H01L 21/67103; H05B 2203/017; H05B 2203/016

(57) ABSTRACT

An electrical interconnect for use in connecting layers of a multi-layer heater includes a shaped body having a lower end portion and an upper end portion. The lower end portion has a smaller contact area than a contact area of the upper end portion, and the contact area of the lower end portion is proximate a heating layer and the contact area of the upper end portion is proximate a routing layer.

### FIELD

The present disclosure relates to electrical interconnections for multi-layer heater constructions.

### BACKGROUND

The statements in this section merely provide background information related to the present disclosure and may not constitute prior art.

Typical multi-layer heater constructions (e.g., ceramic pedestals) may include electrical interconnections between at least two electrically active layers. For example, one or more electrical interconnections may be employed between a heating layer and a subsequent routing layer, which are physically separated through an electrically insulating layer (i.e., dielectric layer). In other examples, a multi-layer heater construction may include several heating layers and several routing layers with electrical interconnections extending between layers and electrical interconnections extending up to the top of the heater assembly, where they may or may not act as a terminal for further electrical connection of the heater.

Challenges associated with electrical interconnections/vias include manufacturing an electrical interconnection/via by means of a conventional tape masking procedure. Such a tape mask typically results in a cylindrical via geometry with sharp outside edges and vertical faces, which pose a challenge during a subsequent coating procedure of a routing layer. Consequently, uniform layer properties are difficult to obtain along such edges and faces. The via could be filled with a conductive material prior to the coating of the routing layer instead, however, additional manufacturing steps would be used, which would complicate the manufacturing process. These challenges, among other challenges in the construction of multi-layer heaters, such as ceramic pedestals in semiconductor processing, are addressed by the present disclosure.

### SUMMARY

This section provides a general summary of the disclosure and is not a comprehensive disclosure of its full scope or all of its features.

In one form, the present disclosure provides an electrical interconnect for use in connecting layers of a multi-layer heater. The electrical interconnect comprises a shaped body having a lower end portion and an upper end portion. The lower end portion has a smaller contact area than a contact area of the upper end portion, and the contact area of the lower end portion is proximate a heating layer and the contact area of the upper end portion is proximate a routing layer.

In variations of the electrical interconnect, which may be implemented individually or in any combination: the shaped body defines a varying circular cross-sectional area; the shaped body comprises a concave radius extending around a periphery and adjacent to the lower end portion of the shaped body; the shaped body comprises a convex radius extending around a periphery and adjacent to the upper end portion of the shaped body; the shaped body defines a sidewall extending at an angle up to about 45 degrees between the lower end portion and the upper end portion; and the shaped body comprises a plurality of individual segments.

In another form, the present disclosure provides a multi-layer heater that comprises a heating layer, a dielectric layer, a routing layer, and at least one via. The dielectric layer is disposed over the heating layer. The routing layer is disposed over the dielectric layer. The via extends from the heating layer, through the dielectric layer, and to the routing layer, thereby forming an electrical interconnect. The via includes a shaped body having a lower end portion and an upper end portion. The lower end portion has a smaller contact area than a contact area of the upper end portion, and the contact area of the lower end portion is proximate the heating layer and the contact area of the upper end portion is proximate the routing layer.

In variations of the multi-layer heater, which may be implemented individually or in any combination: the heating layer comprises a plurality of resistive traces and at least one resistive trace extends near the lower end portion and under the upper end portion of the via; the shaped body defines a varying circular cross-sectional area; the shaped body comprises a concave radius extending around a periphery of the shaped body and adjacent to the lower end portion; the shaped body comprises a convex radius extending around a periphery of the shaped body and adjacent to the upper end portion; the shaped body comprises a plurality of individual segments; the via defines a sidewall extending at an angle up to about 45 degrees through the dielectric layer; and the via extends at least partially into the heating layer.

In yet another form, the present disclosure provides a multi-layer heater that comprises a heating layer, a dielectric layer, and a routing layer. The dielectric layer is disposed over the heating layer and comprises at least one aperture exposing the heating layer. The routing layer is disposed over the dielectric layer and extends into the aperture and onto the heating layer. The aperture is shaped to have a lower end portion and an upper end portion. The lower end portion has a smaller opening than an opening of the upper end portion, and the opening of the lower end portion is proximate the heating layer and the opening of the upper end portion is proximate the routing layer.

In some variations of the multi-layer heater of the above paragraph, a protective layer is formed over the routing layer.

In still yet another form, the present disclosures process of forming a multi-layer heater. The process comprising forming a heating layer; forming a dielectric layer over the heating layer, the dielectric layer comprising at least one aperture exposing the heating layer; and forming a routing layer over the dielectric layer, the routing layer extending into the aperture and onto the exposed heating layer. The aperture is shaped to have a lower end portion and an upper end portion. The lower end portion has a smaller opening than an opening of the upper end portion, and the opening of the lower end portion is proximate the heating layer and the opening of the upper end portion is proximate the routing layer.

In variations of forming the multi-layer heater, which may be implemented individually or in any combination: the aperture is formed by using a mask when forming the dielectric layer; the aperture is formed by removing areas of the dielectric layer with a subtractive process; at least a portion of the heating layer is removed by a subtractive process; the subtractive process is selected from the group consisting of laser ablation, mechanical milling, chemical etching, waterjet, and combinations thereof; the aperture is formed by first depositing and curing a maskant onto the heating layer, applying the dielectric layer over the maskant and the heating layer, removing the maskant, and subsequently removing portions of the dielectric layer to shape the aperture; forming a protective layer over the routing layer; and planarizing an upper surface of the protective layer.

In still yet another form, the present disclosures process of forming a multi-layer heater. The process comprising forming a heating layer; forming a dielectric layer over the heating layer, the dielectric layer comprising at least one aperture exposing the heating layer; forming a via within the at least one aperture, the via being in contact with the heating layer; and forming a routing layer over the dielectric layer, the routing layer being in contact with the via. The aperture is shaped to have a lower end portion and an upper end portion. The lower end portion has a smaller opening than an opening of the upper end portion, and the opening of the lower end portion is proximate the heating layer and the opening of the upper end portion is proximate the routing layer.

Further areas of applicability will become apparent from the description provided herein. It should be understood that the description and specific examples are intended for purposes of illustration only and are not intended to limit the scope of the present disclosure.

### DRAWINGS

In order that the disclosure may be well understood, there will now be described various forms thereof, given by way of example, reference being made to the accompanying drawings, in which:

FIG. 1 is a side view of a ceramic pedestal assembly constructed in accordance with the teachings of the present disclosure;

FIG. 2a is a partial side cross-sectional view of a ceramic pedestal assembly constructed in accordance with the present disclosure with a shaped aperture formed in a dielectric layer of the ceramic pedestal assembly and a routing layer of the ceramic pedestal assembly removed for clarity;

FIG. 2b is a partial side cross-sectional view of the ceramic pedestal assembly of FIG. 2a including the routing layer;

FIG. 2c is a partial side cross-sectional view of an alternate ceramic pedestal assembly including resistive traces formed in a resistive layer of the ceramic pedestal assembly;

FIG. 3a is a partial side cross-sectional view of a ceramic pedestal assembly constructed in accordance with the present disclosure with an alternate shaped aperture formed in a dielectric layer of the ceramic pedestal assembly and a routing layer of the ceramic pedestal assembly removed for clarity;

FIG. 3b is a partial side cross-sectional view of the ceramic pedestal assembly of FIG. 3a including the routing layer;

FIG. 4a is a partial side cross-sectional view of an alternate ceramic pedestal assembly constructed in accordance with the present disclosure;

FIG. 4b is a partial side cross-sectional view of the ceramic pedestal assembly of FIG. 4a with a planarized protective layer over a routing layer of the ceramic pedestal assembly;

FIG. 5 is a flow chart illustrating a method of forming a ceramic pedestal assembly in accordance with the teachings of the present disclosure;

FIG. 6 is a perspective view of a plurality of vias inserted into a substrate with a dielectric layer removed for clarity;

FIG. 7 is a top view of the plurality of vias inserted into the substrate with the dielectric layer removed for clarity;

FIG. 8a is a perspective view of a via shown in FIGS. 6 and 7;

FIG. 8b is another perspective view of the via of FIG. 8a;

FIG. 8c is a side view of the via of FIG. 8a;

FIG. 8d is a top view of the via of FIG. 8a;

FIG. 9a is a perspective view of an alternate via constructed in accordance with the present disclosure;

FIG. 9b is a side view of the via of FIG. 9a; and

FIG. 10 is a flow chart illustrating a method of forming a ceramic pedestal assembly in accordance with the teachings of the present disclosure.

The drawings described herein are for illustration purposes only and are not intended to limit the scope of the present disclosure in any way.

### DETAILED DESCRIPTION

The following description is merely exemplary in nature and is not intended to limit the present disclosure, application, or uses. It should be understood that throughout the drawings, corresponding reference numerals indicate like or corresponding parts and features.

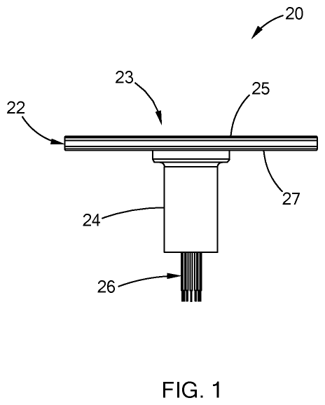

Referring to FIG. 1, a support pedestal 20 constructed in accordance with the teachings of the present disclosure is generally used in a semiconductor processing chamber for supporting and heating a heating target, such as a wafer, thereon. In an exemplary form, the support pedestal 20 includes a ceramic pedestal assembly or multi-layer heater 22 and a tubular shaft 24 attached to a central region 23 of the pedestal assembly 22. The pedestal assembly 22 includes a top surface 25 for supporting a substrate, such as a wafer (not shown) thereon, and a bottom surface 27 to which the tubular shaft 24 is attached. The support pedestal 20 further includes a plurality of electric/power leads 26 received in the tubular shaft 24 for connecting at least one electric element/layer embedded in the pedestal assembly 22 to an external power source. The electric layer may be a resistive heating layer, a temperature sensor, an electrode for an electrostatic chuck (ESC), or a Radio Frequency (RF) antenna, and combinations thereof, among others, depending on the application.

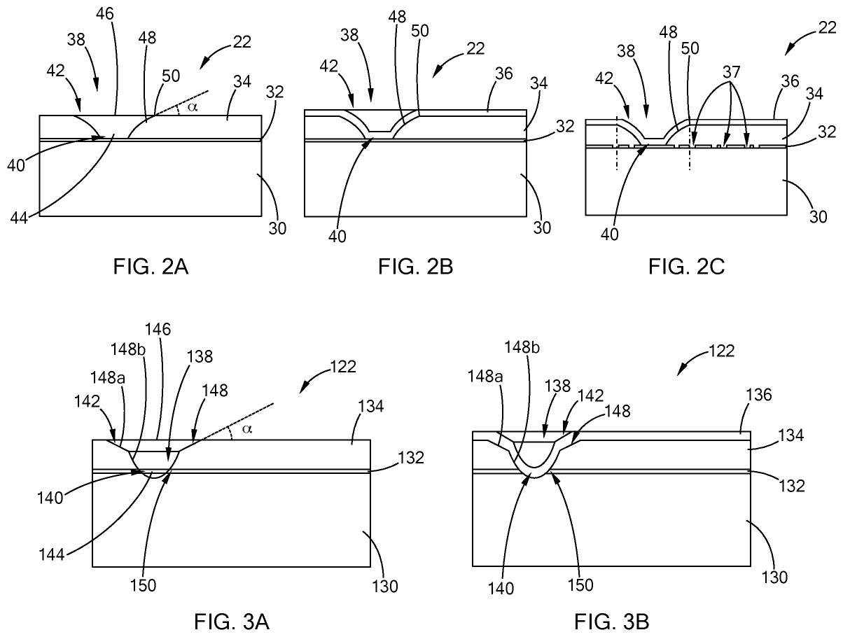

Referring to FIGS. 2a and 2b, a partial side cross-sectional view of the ceramic pedestal assembly 22 is illustrated according to the teachings of the present disclosure. In this form, the ceramic pedestal assembly 22 comprises a ceramic substrate 30, a resistive layer 32, a dielectric layer 34, and a routing layer 36 (FIG. 2b). The resistive layer 32 and the routing layer 36 are disposed on opposite surfaces of the dielectric layer 34 and are disposed in different planes. The resistive layer 32 is also disposed on an upper surface of the ceramic substrate 30 (i.e., disposed between the ceramic substrate 30 and the dielectric layer 34) and generates heat. The resistive layer 32 may include a plurality of resistive heating elements that are independently controllable and may define one or more heating zones. The resistive layer 32 may be formed on the upper surface of the ceramic substrate 30 by, for example, physical vapor deposition (PVD), sputtering, thin foil, thermal spray deposition, or any methods known in the art.

The dielectric layer 34 is disposed on the resistive layer 32 and between the resistive layer 32 and the routing layer 36. The dielectric layer 34 insulates the resistive layer 32 and the routing layer 36, and in one form includes at least one aperture 38 exposing the resistive layer 32. As shown, the aperture 38 is shaped to define a varying circular cross-sectional area. However, it should be understood that the cross-sectional may be another suitable shape besides circular (such as by way of example, elliptical or polygonal) and should not be limited to a circular cross-section as illustrated herein. The aperture 38 is shaped to have a lower end portion 40 and an upper end portion 42. The lower end portion 40 has an opening 44 that is smaller than an opening 46 of the upper end portion 42. The opening 44 of the lower end portion 40 is proximate the resistive layer 32 and the opening 46 of the upper end portion 42 is proximate the routing layer 36. The aperture 38 also defines a sidewall 48 extending at an angle α between the lower end portion 40 and the upper end portion 42. In one form the angle α is equal to or less than 45 degrees. As further shown in this form, the sidewall 48 increases in slope towards the center of the aperture 38 down to the resistive layer 32. The aperture 38 also has a smooth outside edge 50 in this form.

The routing layer 36 is disposed on the dielectric layer 34 and extends into the aperture 38 (i.e., disposed on the sidewall 48 of the aperture 38) and onto the exposed resistive layer 32. The routing layer 36 is disposed on the exposed resistive layer 32 in a central area of the aperture 38, thereby forming an electrical connection by a planar contact between the routing layer 36 and the resistive layer 32. In this way, the routing layer 36 electrically connected to one or more of the cables 26 supplies power to one or more zones of the resistive layer 32. In this form, the resistive layer 32 is continuous in the area where the electrical connection is formed (i.e., in the area where there is a planar contact between the routing layer 36 and the resistive layer 32). In some examples, as shown in FIG. 2c, the resistive layer 32 includes a plurality of resistive traces 37 with at least one resistive trace 37 extending near the lower end portion 40 and under the upper end portion 42 of the aperture 38. In this way, the resistive traces 37 can be more densely located in the area forming the electrical connection to reduce cold spots that may result from not actively heating the area forming the electrical connection.

Referring to FIGS. 3a and 3b, a partial side cross-sectional view of the ceramic pedestal assembly 122 is illustrated according to the teachings of the present disclosure. The structure and function of the ceramic pedestal assembly 122 may be similar or identical to the pedestal assembly 22 described above, apart from any exception noted below. The ceramic pedestal assembly 122 comprises a ceramic substrate 130, a resistive layer 132, a dielectric layer 134, and a routing layer 136 (FIG. 3b). The resistive layer 132 and the routing layer 136 are disposed on opposite surfaces of the dielectric layer 134 and are disposed in different planes. The resistive layer 132 is also disposed on an upper surface of the ceramic substrate 130 (i.e., disposed between the ceramic substrate 130 and the dielectric layer 134) and generates heat. The resistive layer 132 may be formed on the upper surface of the ceramic substrate 130 by, for example, physical vapor deposition (PVD), sputtering, thin foil, thermal spray deposition, or any methods known in the art.

The dielectric layer 134 is disposed on the resistive layer 132 and between the resistive layer 132 and the routing layer 136. The dielectric layer 134 generally insulates the resistive layer 132 and the routing layer 136, and in one form includes at least one aperture 138 exposing the resistive layer 132 and the ceramic substrate 130. The aperture 138 is shaped to have a lower end portion 140 and an upper end portion 142. The lower end portion 140 has an opening 144 that is smaller than an opening 146 of the upper end portion 142. The opening 144 of the lower end portion 140 is proximate the resistive layer 132 and the opening 146 of the upper end portion 142 is proximate the routing layer 136. The aperture 138 also defines a sidewall 148 having a first portion 148a and a second portion 148b. The first portion 148a has a linear surface and is positioned proximate the routing layer 136. The first portion 148a also extends at an angle α between the lower end portion 140 and the upper end portion 142. The angle α may be equal to or less than 45 degrees. The second portion 148b has a non-linear surface and is positioned proximate the resistive layer 132. In the example provided, the second portion 148b has an elliptical shape, however, in some forms, the second portion 148b may be another suitable shape (e.g., a spherical shape).

The routing layer 136 is disposed on the dielectric layer 134 and extends into the aperture 138 (i.e., disposed on the first and second portions 148a, 148b of the sidewall 148). In some configurations, as shown in FIG. 3b, the resistive layer 132 may be discontinuous at an area proximate the aperture 138 as a result of the aperture 138 formed in the dielectric layer 134 extending through the resistive layer 132 and at least partially through the ceramic substrate 130. The routing layer 136 disposed on the dielectric layer 134 may contact the resistive layer 132 along a ring-shaped area 150 thereof, thereby forming an electrical connection.

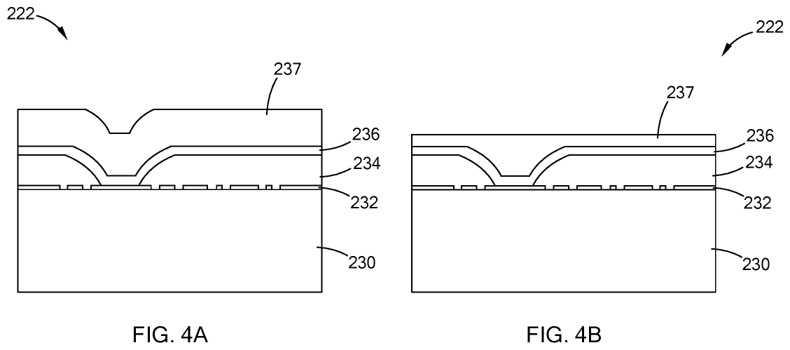

Referring to FIGS. 4a and 4b, a partial side cross-sectional view of the ceramic pedestal assembly 222 is illustrated according to the teachings of the present disclosure. The structure and function of the ceramic pedestal assembly 222 may be similar or identical to the pedestal assemblies 22, 122 described above, apart from any exception noted below. The ceramic pedestal assembly 222 comprises a ceramic substrate 230, a resistive layer 232, a first dielectric layer 234, a routing layer 236, and a second dielectric layer 237. The structure and function of the ceramic substrate 230, the resistive layer 232, the first dielectric layer 234, and the routing layer 236 may be similar or identical to the ceramic substrate, 30, the resistive layer 32, the dielectric layer 34, and the routing layer 236, respectively, described above, and therefore, will not be described again in detail.

The second dielectric layer 237 is disposed on the routing layer 236 and electrically and mechanically insulates the routing layer 236 from external influences. In one form, the second dielectric layer 237 is planarized using a subtractive process such as by way of example laser ablation, mechanical milling, chemical etching, waterjet, and combinations thereof, among others. In this way, an even surface is provided for the subsequent assembly of a multi-layer heater engine.

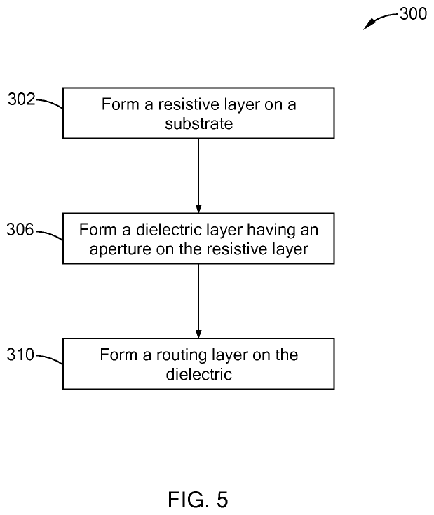

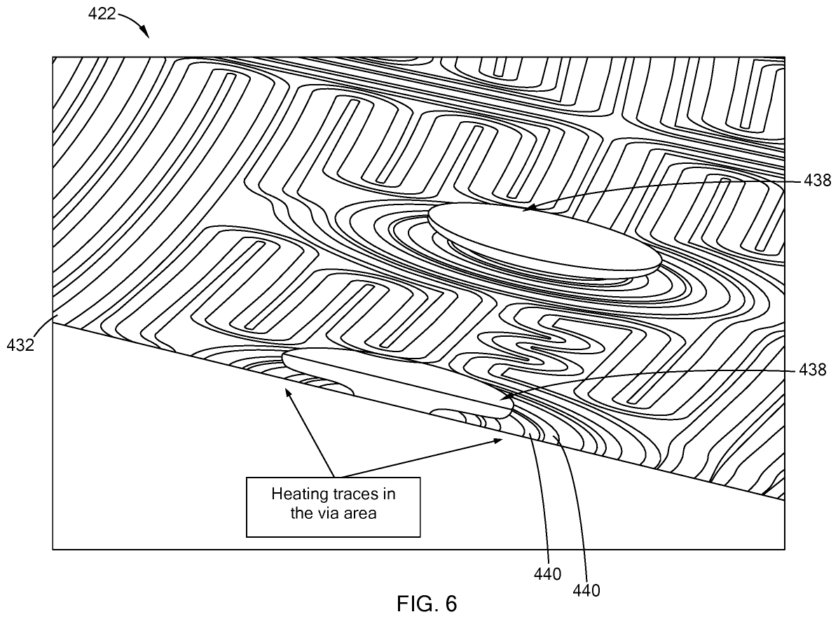

Referring to FIG. 5 a method 300 of forming a ceramic pedestal assembly, as described above, is illustrated in schematic form. At 302, a resistive layer is formed on an upper surface of the ceramic substrate. The resistive layer may be formed on the upper surface of the ceramic substrate by, for example, physical vapor deposition (PVD), sputtering, thin foil, thermal spray deposition, or any methods known in the art.

Next, at 306, a dielectric layer is formed over the resistive layer. The dielectric layer includes at least one aperture exposing the resistive layer. In one form, the aperture is formed by using a mask when forming the dielectric layer. In another form, the aperture is formed by removing areas of the dielectric layer with a substrative process. The substrative process is selected from the group consisting of laser ablation, mechanical milling, chemical etching, waterjet, and combinations therefor. In this way, the aperture is shaped to have a lower end portion, an upper end portion, and a sidewall extending at an angle between the lower end portion and the upper end portion. The lower end portion has an opening that is smaller than an opening of the upper end portion. The angle may be equal to or less than 45 degrees.

Lastly, at 310, a routing layer is formed over the dielectric layer and extends into the aperture (i.e., disposed on the sidewall of the aperture) and onto the exposed resistive layer. The routing layer may be formed using thermal spray deposition, for example, such that an electrical interconnection with a defined thickness is formed from the routing layer down to the resistive layer.

The method 300 is just one example of forming the ceramic pedestal assembly of the present disclosure and may include other or alternate steps. For example, in another form, the method 300 further includes removing at least a portion of the resistive layer by a substrative process (FIGS. 3a and 3b).

In yet another form, the method 300 includes forming the aperture by first depositing and curing a liquid maskant onto the resistive layer, applying the dielectric layer over the maskant and the resistive layer, removing the maskant, and subsequently removing portions of the dielectric layer using a subtractive process to shape the aperture. The liquid maskant may be a UV (ultraviolet) curable maskant, for example.

In still another form, the method 300 may include forming a protective layer over the routing layer and planarizing an upper surface of the protective layer (FIG. 4b).

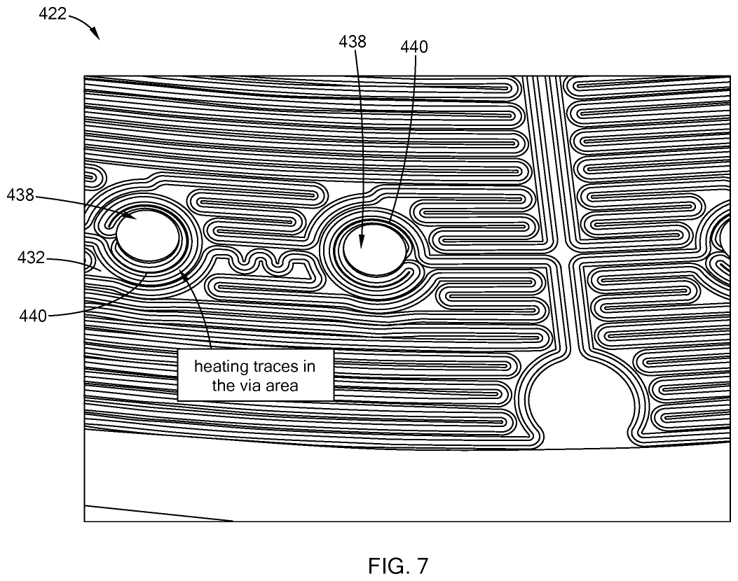

Referring to FIGS. 6 and 7, a multi-layer heater 422 is illustrated. The multi-layer heater 422 comprises a ceramic substrate (not shown), a resistive layer 432, a dielectric layer (not shown), a routing layer (not shown), and a plurality of vias 438. The resistive layer 432 and the routing layer are disposed on opposite surfaces of the dielectric layer and are disposed in different planes. The resistive layer 432 is also disposed on an upper surface of the ceramic substrate (i.e., disposed between the ceramic substrate and the dielectric layer) and generates heat. The resistive layer 432 is in contact with the vias 438 and includes a plurality of resistive traces 440. The resistive layer 432 may be formed on the upper surface of the ceramic substrate by, for example, physical vapor deposition (PVD), sputtering, thin foil, thermal spray depositions, or any methods known in the art.

The dielectric layer (not shown) is disposed on the resistive layer 432 and between the resistive layer 432 and the routing layer. The dielectric layer generally insulates the resistive layer 432 and the routing layer, and in one form includes at least one aperture (not shown) exposing the resistive layer. The aperture is shaped to define a varying circular cross-sectional area. However, it should be understood that the cross-sectional may be another suitable shape as set forth above and should not be limited to a circular cross-section. The structure of the aperture may be similar or identical to the apertures 38, 138 described above, and therefore, will not be described again in detail. The routing layer is disposed on the dielectric layer and in contact with the vias 438.

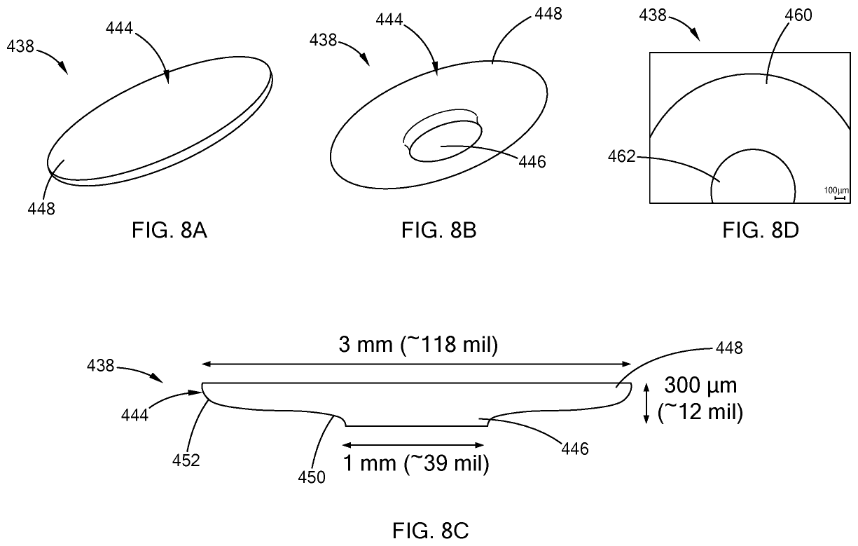

With additional reference to FIGS. 8a-8d, one via 438 of the plurality of vias 438 is illustrated. Each via 438 extends from the resistive layer 432, through the dielectric layer, and to the routing layer, thereby forming an electrical interconnect. Each via 438 includes a shaped body 444 having a lower end portion 446 and an upper end portion 448. The lower end portion 446 has a smaller contact area than a contact area of the upper end portion 448. For example, the lower end portion 446 may have a contact area expanding a diameter of 1 millimeter (mm), for example, while the upper end portion 448 has a contact area expanding a diameter of 3 millimeters (mm), for example. A length of the via 438 from the lower end portion 446 to the upper end portion 448 may be 300 microns (μm), for example. The contact area of the lower end portion 446 is proximate a heating layer and the contact area of the upper end portion 448 is proximate a routing layer. The shaped body 444 has a varying circular cross-sectional area. In some configurations, the shaped body 444 cross-sectional area may have a different varying shape. The shaped body 444 includes a concave radius 450 extending around a periphery and adjacent to the lower end portion 446 of the shaped body 444. The shaped body 444 also includes a convex radius 452 extending around a periphery and adjacent to the upper end portion 448 of the shaped body 444. At least one resistive trace 440 (FIGS. 6 and 7) extends near the lower end portion 446 and under the upper end portion 448 of the via 438. In this way, the resistive traces 440 can be pulled in the area forming the electrical interconnect to reduce cold spots of the unheated area. One or more of the resistive traces 440 may be in a circle around the via 438 (best seen in FIG. 7) to prevent high potential difference between the via 438 and surrounding parts of the circuitry on the resistive layer 432.

In some forms, as shown in FIG. 8d, the via 438 may have a cavity 460 filled with an electrically conductive material such as tin 462, for example, at the lower end portion 446 to facilitate the electrical interconnect to other electro-mechanical components of the multi-layer heater 422. Such filling of the cavity 460 with tin 462 may be done in a dedicated process such as an ultrasonic soldering process.

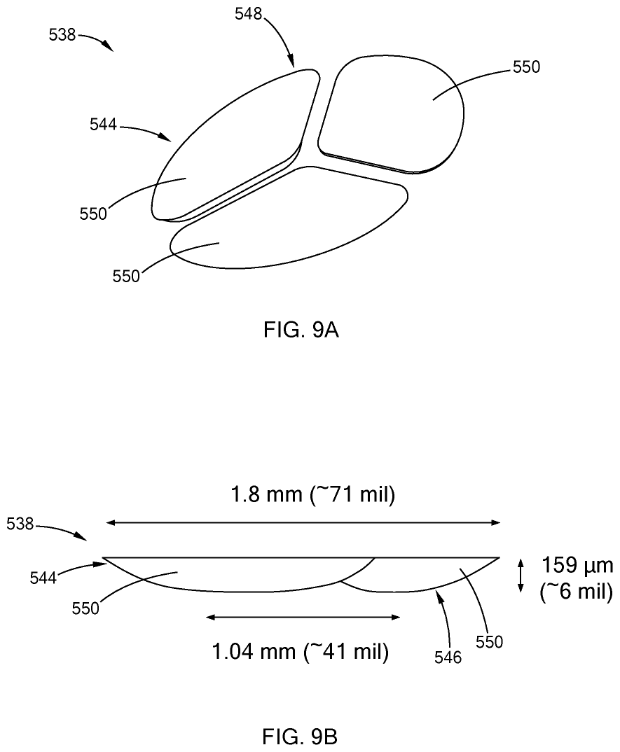

Referring to FIGS. 9a and 9b, another via 538 is illustrated. The via 538 may be incorporated into the multi-layer heater 422 instead of, or in addition to, via 438. The structure and function of the via 538 may be similar or identical to the via 438, apart from any exception noted below.

The via 538 includes a shaped body 544 having a lower end portion 546 and an upper end portion 548. The lower end portion 546 has a smaller contact area than a contact area of the upper end portion 548. The contact area of the lower end portion 546 is proximate a heating layer and the contact area of the upper end portion 548 is proximate a routing layer. The shaped body 544 of the via 538 also includes a plurality of individual segments 550 that are spaced apart from each other. It is understood that although 3 segments are shown, the via 538 may include more or less individual segments 550. The spaces between the segments 550 are filled with an electrically conductive material, and thus the segmentation provides improved adhesion of subsequent layers. The via 538 also includes a certain redundancy in case one of the segments defaults then the other remaining segments can take over the current load.

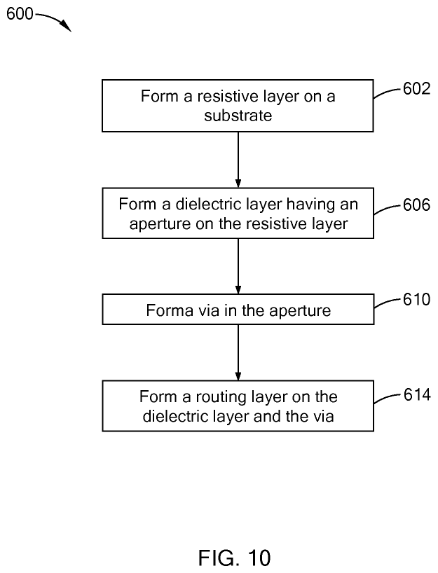

Referring to FIG. 10 a method 600 of forming a ceramic pedestal assembly, as described above, is illustrated in schematic form. At 602, a resistive layer is formed on an upper surface of the ceramic substrate. The resistive layer may be formed on the upper surface of the ceramic substrate by, for example, physical vapor deposition (PVD), sputtering, thin foil, thermal spray deposition, or any methods known in the art.

Next, at 606, a dielectric layer is formed over the resistive layer. The dielectric layer includes at least one aperture exposing the resistive layer. In one form, the aperture is formed by using a mask when forming the dielectric layer. In another form, the aperture is formed by removing areas of the dielectric layer with a substrative process. The substrative process is selected from the group consisting of laser ablation, mechanical milling, chemical etching, waterjet, and combinations therefor. In this way, the aperture is shaped to have a lower end portion, an upper end portion, and a sidewall extending at an angle between the lower end portion and the upper end portion. The lower end portion has an opening that is smaller than an opening of the upper end portion. The angle may be equal to or less than 45 degrees.

Next, at 610, a via is formed within the at least one aperture of the dielectric layer. The via is in contact with the resistive layer and may have a shape that corresponds to the aperture of the dielectric layer.

Lastly, at 614, a routing layer is formed over the dielectric layer and is in contact with the via, thereby forming an electrical interconnect. The routing layer may be formed using thermal spray deposition, for example.

It should be understood that the ceramic pedestal assembly is not limited by the specific multi-layered structure and the pedestal assembly may further comprise additional functional layers (e.g., bonding layer, dielectric layers, sensing layer, and protective layer, among others) while still remaining within the scope of the present disclosure. In one example, the pedestal assembly further comprises additional heating layers and routing layers with interconnections buried in between layers and interconnections reaching up to the top of the heater configuration where the interconnections may or may not act as a terminal for further electrical contacting of the heater construction (e.g., through hole or blind via with or without electrically interfacing to external components).

The ceramic pedestal assembly of the present disclosure provides the benefit of an electrical interconnect having a shape that improves the heaters thermal signature. The present disclosure also provides the benefit of improving the manufacturing process of the ceramic pedestal assembly (e.g., reducing manufacturing steps while allowing the manufacturing process to be semi or fully automated). The ceramic pedestal assembly of the present disclosure also provides the benefit of an electrical interconnect with smooth outside edges, which provides high operating reliability especially when depositing the routing layer using thermal spray deposition.

Unless otherwise expressly indicated herein, all numerical values indicating mechanical/thermal properties, compositional percentages, dimensions and/or tolerances, or other characteristics are to be understood as modified by the word “about” or “approximately” in describing the scope of the present disclosure. This modification is desired for various reasons including industrial practice, material, manufacturing, and assembly tolerances, and testing capability.

As used herein, the phrase at least one of A, B, and C should be construed to mean a logical (A OR B OR C), using a non-exclusive logical OR, and should not be construed to mean “at least one of A, at least one of B, and at least one of C.”

The description of the disclosure is merely exemplary in nature and, thus, variations that do not depart from the substance of the disclosure are intended to be within the scope of the disclosure. Such variations are not to be regarded as a departure from the spirit and scope of the disclosure.

What is claimed is:

1. An electrical interconnect for use in connecting layers of a multi-layer heater, the electrical interconnect comprising a shaped body having a lower end portion and an upper end portion, wherein the lower end portion has a smaller contact area than a contact area of the upper end portion, and the contact area of the lower end portion is proximate a heating layer and the contact area of the upper end portion is proximate a routing layer.

2. The electrical interconnect according to claim 1, wherein the shaped body defines a varying circular cross-sectional area.

3. The electrical interconnect according to claim 1, wherein the shaped body comprises a concave radius extending around a periphery and adjacent to the lower end portion of the shaped body.

4. The electrical interconnect according to claim 1, wherein the shaped body comprises a convex radius extending around a periphery and adjacent to the upper end portion of the shaped body.

5. The electrical interconnect according to claim 1, wherein the shaped body defines a sidewall extending at an angle up to about 45 degrees between the lower end portion and the upper end portion.

6. The electrical interconnect according to claim 1, wherein the shaped body comprises a plurality of individual segments.

7. A multi-layer heater comprising:
a heating layer;
a dielectric layer disposed over the heating layer;
a routing layer disposed over the dielectric layer; and
at least one via extending from the heating layer, through the dielectric layer, and to the routing layer, thereby forming an electrical interconnect, the at least one via comprising:
a shaped body having a lower end portion and an upper end portion,
wherein the lower end portion has a smaller contact area than a contact area of the upper end portion, and the contact area of the lower end portion is proximate the heating layer and the contact area of the upper end portion is proximate the routing layer.

8. The multi-layer heater according to claim 7, wherein the heating layer comprises a plurality of resistive traces and at least one resistive trace extends near the lower end portion and under the upper end portion of the at least one via.

9. The multi-layer heater according to claim 7, wherein the shaped body defines a varying circular cross-sectional area.

10. The multi-layer heater according to claim 7, wherein the shaped body comprises a concave radius extending around a periphery of the shaped body and adjacent to the lower end portion.

11. The multi-layer heater according to claim 7, wherein the shaped body comprises a convex radius extending around a periphery of the shaped body and adjacent to the upper end portion.

12. The multi-layer heater according to claim 7, wherein the shaped body comprises a plurality of individual segments.

13. The multi-layer heater according to claim 7, wherein the at least one via defines a sidewall extending at an angle up to about 45 degrees through the dielectric layer.

14. The multi-layer heater according to claim 7, wherein the at least one via extends at least partially into the heating layer.

15. A multi-layer heater comprising:
a heating layer;
a dielectric layer disposed over the heating layer, the dielectric layer comprising at least one aperture exposing the heating layer; and
a routing layer disposed over the dielectric layer and extending into the aperture and onto the heating layer,
wherein the aperture is shaped to have a lower end portion and an upper end portion, wherein the lower end portion has a smaller opening than an opening of the upper end portion, and the opening of the lower end portion is proximate the heating layer and the opening of the upper end portion is proximate the routing layer.

16. The multi-layer heater according to claim 15, further comprising a protective layer formed over the routing layer.

17. A multi-layer heater formed by a process of:
forming a heating layer;
forming a dielectric layer over the heating layer, the dielectric layer comprising at least one aperture exposing the heating layer; and
forming a routing layer over the dielectric layer, the routing layer extending into the aperture and onto the exposed heating layer,
wherein the aperture is shaped to have a lower end portion and an upper end portion, wherein the lower end portion has a smaller opening than an opening of the upper end portion, and the opening of the lower end portion is proximate the heating layer and the opening of the upper end portion is proximate the routing layer.

18. The multi-layer heater according to claim 17, wherein the aperture is formed by using a mask when forming the dielectric layer.

19. The multi-layer heater according to claim 17, wherein the aperture is formed by removing areas of the dielectric layer with a subtractive process.

20. The multi-layer heater according to claim 19, wherein at least a portion of the heating layer is removed by a subtractive process.

21. The multi-layer heater according to claim 19, wherein the subtractive process is selected from the group consisting of laser ablation, mechanical milling, chemical etching, waterjet, and combinations thereof.

22. The multi-layer heater according to claim 17, wherein the aperture is formed by first depositing and curing a maskant onto the heating layer, applying the dielectric layer over the maskant and the heating layer, removing the maskant, and subsequently removing portions of the dielectric layer to shape the aperture.

23. The multi-layer heater according to claim 17, further comprising forming a protective layer over the routing layer.

24. The multi-layer heater according to claim 23, further comprising planarizing an upper surface of the protective layer.

25. A multi-layer heater formed by a process of:
forming a heating layer;
forming a dielectric layer over the heating layer, the dielectric layer comprising at least one aperture exposing the heating layer;
forming a via within the at least one aperture, the via being in contact with the heating layer; and
forming a routing layer over the dielectric layer, the routing layer being in contact with the via,
wherein the aperture is shaped to have a lower end portion and an upper end portion, wherein the lower end portion has a smaller opening than an opening of the upper end portion, and the opening of the lower end portion is proximate the heating layer and the opening of the upper end portion is proximate the routing layer.
